(19) United States
(12) Patent Application Publication
(10) Pub. No.: US 2024/0343556 A1
(43) Pub. Date: Oct. 17, 2024

(54) MICROMECHANICAL COMPONENT AND SCANNING DEVICE

(71) Applicant: Robert Bosch GmbH, Stuttgart (DE)

(72) Inventors: Helmut Grutzeck, Kusterdingen (DE); Josip Mihaljevic, Holzgerlingen (DE); Philipp Matthias Roming, Schramberg (DE); Udo Hartel, Renningen (DE)

(21) Appl. No.: 18/588,988

(22) Filed: Feb. 27, 2024

(30) Foreign Application Priority Data
Apr. 13, 2023 (DE) 10 2023 203 335.6

(51) Int. Cl. B81B 3/00; G02B 26/08

(52) U.S. Cl. CPC B81B 3/007; G02B 26/0833; B81B 2201/042; B81B 2207/015; B81B 2207/03; B81B 2207/07

(57) ABSTRACT

A micromechanical component. The micromechanical component includes at least one adjustable part, a first holder for the adjustable part, and a first connecting structure. The first connecting structure is designed to connect the adjustable part to the first holder along a first axis of symmetry of the adjustable part, which runs perpendicular to an axis of rotation of the adjustable part. The micromechanical component further includes a first electrical conductor for detecting a breakage within the first connecting structure. The electrical conductor runs along the first connecting structure at least partially at an angle to the first axis of symmetry of the adjustable part.

### CROSS REFERENCE

The present application claims the benefit under 35 U.S.C. § 119 of German Patent Application No. DE 10 2023 203 335.6 filed on Apr. 13, 2023, which is expressly incorporated herein by reference in its entirety.

### FIELD

The present invention relates to a micromechanical component and a scanning device comprising the micromechanical component.

### BACKGROUND INFORMATION

German Patent Application No. DE 10 2013 217 094 A1 describes a micromechanical component including an electrical conductor for breakage detection within a connecting structure of a micromirror with a holder of the micromirror. The electrical conductor runs essentially parallel to a first axis of symmetry of the adjustable part that runs perpendicular to an axis of rotation of the adjustable part. However, the electrical conductor as breakage resistance or its additional functional layers provide additional stiffening of the connecting structure within the connecting structure, which can lead to the breakage being routed around the electrical conductor and thus not being detected.

Proceeding from this starting point, an object of the present invention to provide a micromechanical component that solves this problem.

### SUMMARY

To solve the problem, a micromechanical component, in particular a micromirror device, and a scanning device are provided.

According to an example embodiment of the present invention, the micromechanical component comprises at least one adjustable part, a first holder for the adjustable part and a first connecting structure. In this context, the first connecting structure is configured to connect the adjustable part to the first holder along a first axis of symmetry of the adjustable part that runs perpendicular to an axis of rotation of the adjustable part. Furthermore, the micromechanical component also has a first electrical conductor for detecting a breakage within the first connecting structure. The first electrical conductor in this case runs along the first connecting structure at least partially at an angle to the first axis of symmetry of the adjustable part. The term “at an angle” refers in particular to an angle between 0° and 90° relative to the first axis of symmetry. The angle here refers in particular to the angle that is included between the first axis of symmetry and the electrical conductor. In particular, the first electrical conductor runs at least partially at an angle, away from the first axis of symmetry. Due to the fact that the electrical conductor runs at least partially at an angle along the connecting structure, the stress concentration or the load on the first connecting element during operation of the micromechanical component is concentrated more in the center of the connecting structure. A possible breakage within the first connecting structure is therefore guided more in the direction of the first electrical conductor and can be detected there.

Preferably, according to an example embodiment of the present invention, the first electrical conductor runs essentially parallel to the first axis of symmetry in a first region of the first connecting structure that is aligned towards the first holder and partially at an angle to the first axis of symmetry in a second region of the first connecting structure that is aligned towards the adjustable part. In this way, the connecting structure is additionally stiffened in the second region aligned towards the adjustable part, which means that the breakage is directed more towards the less stiffened area and thus towards the holder. The breakage can therefore be reliably detected. Preferably, the first electrical conductor, in particular in a plan view, comprises a combined Y-shape in the first and second regions. The introduction of the electrical conductor or its additional functional layers also changes the thermal behavior of the structure. The Y-shape only has a small additional surface area to achieve the stiffening effect, which also minimizes the generation of thermal deformation.

According to an example embodiment of the present invention, preferably, the first electrical conductor runs at an angle to the first axis of symmetry in a third region of the first connecting structure that is aligned towards the first holder. In a fourth, central region of the first connecting structure, the first electrical conductor runs essentially parallel to the first axis of symmetry, and in a fifth region of the first connecting structure, which is aligned towards the adjustable part, the first electrical conductor runs at least partially at an angle to the first axis of symmetry. This course of the first electrical conductor along the first connecting structure shifts the stress concentration even more into the central region of the first connecting structure. This leads to even more reliable breakage detection.

Preferably, according to an example embodiment of the present invention, the first electrical conductor runs along the first connecting structure completely at an angle to the first axis of symmetry. In this context, the first electrical conductor has several, in particular at least two, changes of direction along its course. This means that a possible breakage or crack is guided even more strongly into the first connecting structure.

Preferably, according to an example embodiment of the present invention, the first electrical conductor is configured to be symmetrical to the first axis of symmetry along the first connecting structure, in particular in a plan view.

Preferably, according to an example embodiment of the present invention, the first holder has a frame shape. The holder therefore completely frames the adjustable part, which results in a high level of stability.

Preferably, according to an example embodiment of the present invention, the micromechanical component also has a second connecting structure. The second connecting structure is designed to additionally connect the adjustable part to the first holder along the first axis of symmetry of the adjustable part. The first electrical conductor or, alternatively, a second electrical conductor of the micromechanical component are designed to detect a breakage within the second connecting structure and, for this purpose, run along the second connecting structure partially at an angle to the first axis of symmetry of the adjustable part. The first connecting structure and the second connecting structure are arranged on opposite sides of the adjustable part. Preferably, the first electrical conductor runs from the first connecting structure to the second connecting structure along the first holder. Furthermore, the first electrical conductor preferably completely surrounds the adjustable part.

Preferably, according to an example embodiment of the present invention, the first electrical conductor runs partly on and/or inside the adjustable part. This serves to detect a breakage within the connecting structure even more reliably and to prevent the breakage from being routed around the electrical conductor. However, on account of the mechanical and thermal properties of the adjustable part being altered by the stiffening, it is preferably provided that the electrical conductor protrudes as little as possible into the surface of the adjustable part. Preferably, the electrical conductor in this context is only arranged in a transition region of the first connecting structure and/or the second connecting structure towards the adjustable part.

Preferably, according to an example embodiment of the present invention, the first connecting structure and/or second connecting structure are designed as webs. In particular, the webs have a length of 100 to 200 μm, a width of 350 to 450 μm and a thickness of 25 to 35 μm.

Preferably, according to an example embodiment of the present invention, the micromechanical component has a second, in particular fixed, holder and a first and second spring. The first spring and second spring are designed to suspend the first holder from the second holder, in particular adjustably about the axis of rotation of the adjustable part. In this context, the first spring and second spring are preferably designed as torsion springs.

A further subject matter of the present invention is a scanning device, in particular a microscanning device. According to an example embodiment of the present invention, the scanning device comprises the micromechanical component described above. In this context, the scanning device is preferably configured as a LIDAR scanner. Alternatively, the scanning device is configured as a microscanner for projection onto a screen or onto the eye of a user of smart glasses.

### BRIEF DESCRIPTION OF THE DRAWINGS

FIG. 1 shows a micromechanical component with a first embodiment of a first electrical conductor for detecting a breakage within a first connecting structure and a second connecting structure, according to the present invention.

FIG. 2 shows a second embodiment of the first electrical conductor for detecting a breakage within the first connecting structure, according to the present invention.

FIG. 3 shows a third embodiment of the first electrical conductor for detecting a breakage within the first connecting structure, according to the present invention.

FIG. 4 shows a fourth embodiment of the first electrical conductor for detecting a breakage within the first connecting structure, according to present invention.

FIG. 5 shows a scanning device, according to an example embodiment of the present invention.

### DETAILED DESCRIPTION OF EXAMPLE EMBODIMENTS

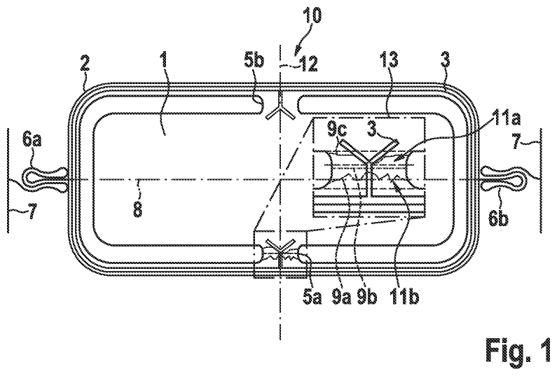

FIG. 1 schematically shows an embodiment of a micromechanical component 10 in the form of a micromirror device. The micromechanical component 10 comprises an adjustable part 1 in the form of a micromirror. In addition, the micromechanical component 10 comprises a first holder 2 for the adjustable part 1. In this embodiment, the holder 2 has a frame shape. Furthermore, the micromechanical component 10 comprises a first connecting structure 5a. The first connecting structure 5a is designed to connect the adjustable part 1 to the first holder 2 along a first axis of symmetry 12 of the adjustable part 1 that runs perpendicular to an axis of rotation 8 of the adjustable part 1. Furthermore, the micromechanical component 1 comprises a first electrical conductor 3 for detecting a breakage 9a to 9c within the first connecting structure 5a. The first electrical conductor 3 runs along the first connecting structure 5a partially at an angle to the first axis of symmetry 12 of the adjustable part 1. The magnified section 13 shows, on the basis of the first connecting structure 5a, how the first electrical conductor 3 runs essentially parallel to the first axis of symmetry 12 in a first region 11b of the first connecting structure 5a that is aligned towards the first holder 2. In a second region 11a of the first connecting structure 5a, which is aligned towards the adjustable part 1, the first electrical conductor 3 again runs at an angle to the first axis of symmetry 12. Due to the inclined course of the first electrical conductor 3 in the direction of the adjustable part 1, the first connecting structure 5a is additionally stiffened in the direction of the adjustable part 1. Thus, the stress within the first connecting structure 5a is concentrated more in the direction of the first holder 2 during operation of the micromechanical component 10. As a result, all the breakages 9a to 9c shown as examples run through the first electrical conductor 3 within the first connecting structure 5a and can be detected accordingly.

In the top view of the micromechanical component 10 shown, the first electrical conductor 3 in the first region 11b and the second region 11a of the first connecting structure 5a together have a Y-shaped profile. In the first embodiment shown, the first electrical conductor 3 is designed to be symmetrical to the first axis of symmetry 12 along the first connecting structure 5a.

Furthermore, the micromechanical component 10 also has a second connecting structure 5b, which is also designed to connect the adjustable part 1 to the first holder 2 along the first axis of symmetry 12 of the adjustable part 1. The first electrical conductor 3 of the micromechanical component 10 is designed to detect a breakage within the second connecting structure 5b and for this purpose runs along the second connecting structure 5b partially at an angle to the first axis of symmetry 12 of the adjustable part 1. The first connecting structure 5a and the second connecting structure 5b are arranged on opposite sides of the adjustable part 1. The first electrical conductor 3 runs from the first connecting structure 5a to the second connecting structure 5b along the first holder 2 and completely frames the adjustable part 1.

The first electrical conductor 3 protrudes slightly from the first connecting structure 5a and the second connecting structure 5b onto the surface of the adjustable part 1 and thus runs partially on and/or inside the adjustable part 1. This means that the breakages within the first connecting structure 5a and/or within the second connecting structure 5b are reliably detected and do not run around the first electrical conductor 3.

In the embodiment shown, the first connecting structure 5a and the second connecting structure 5b are designed as webs. In the case shown, the adjustable part 1, the first holder 1 [sic]¹, as well as the first and second connecting structures 5a and 5b are formed in one piece. ¹ [Translator's note: “Halterung 1” (“holder 1”) should likely be “Halterung 2” (“holder 2”).]

Furthermore, the micromechanical component 10 comprises a second, fixed holder 7, as well as a first spring 6a and second spring 6b in the form of torsion springs. The first spring 6a and the second spring 6b are designed to suspend the first holder 2 from the second holder 7 adjustably about the first axis of rotation 8 of the adjustable part 1.

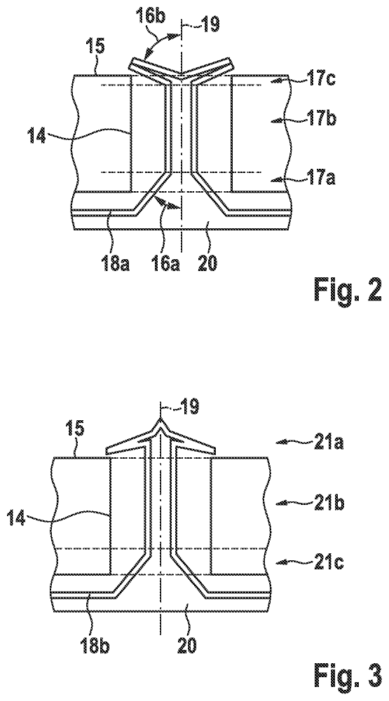

FIG. 2 shows a section of a second embodiment of a first electrical conductor 18a for detecting a breakage within a first connecting structure 14. The first connecting structure 14 serves to connect the adjustable part 15 to the first holder 20 along a first axis of symmetry 19 of the adjustable part 15, which runs perpendicular to an axis of rotation (not shown here) of the adjustable part 15. In contrast to the embodiment of FIG. 1, the first electrical conductor 18a here runs in a third region 17a of the first connecting structure 14, which is aligned towards the first holder 20, at an angle to the first axis of symmetry. The angle 16a indicates the angle enclosed by the first axis of symmetry 19 and the first electrical conductor 18a. The angle is in the inclined region between 0° and 90° relative to the first axis of symmetry. In a fourth, central region 17b of the first connecting structure 14, the first electrical conductor 18a runs essentially parallel to the first axis of symmetry 19, and in a fifth region 17c of the first connecting structure 14, which is aligned towards the adjustable part 15, the first electrical conductor 18a runs at an angle 16b to the first axis of symmetry 19. This concentrates the stress even more within the first connecting structure 14.

FIG. 3 shows a section of a third embodiment of a first electrical conductor 18b for detecting a breakage within the first connecting structure 14. In this case, the first electrical conductor 18b runs at an angle to the first axis of symmetry 19 in a sixth region 21c which is aligned towards the first holder 20. In a seventh region 21b, aligned towards the adjustable part 15, the first electrical conductor runs essentially parallel to the first axis of symmetry 19. In an eighth transition region 21a of the first connecting structure 14 towards the adjustable part 15, the first electrical conductor 18b again runs at an angle to the first axis of symmetry 19 and thus protrudes slightly into the surface (not shown here) of the adjustable part 15. The two regions that run at an angle again ensure that the stress is concentrated within the first connecting structure 14 under load.

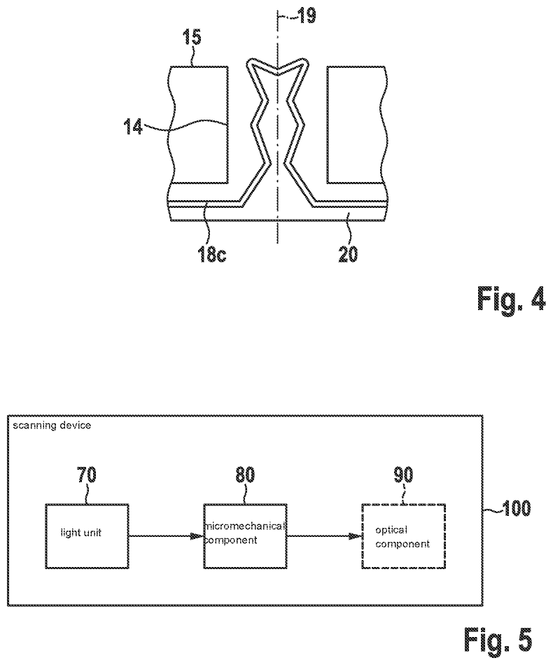

FIG. 4 shows a section of a fourth embodiment of a first electrical conductor 18c for detecting a breakage within the first connecting structure 14. In this case, the first electrical conductor 18c runs along the first connecting structure 14c completely at an angle to the first axis of symmetry 19 and has several changes of direction. The breakage is thus “provoked” when cracks occur in the first connecting structure 14, which is why the first electrical conductor 18c hardly needs to protrude into the surface of the adjustable part 15 for reliable breakage detection.

FIG. 5 schematically shows a microscanning device as scanning device 100. The scanning device 100 in this case comprises a light unit 70 for generating light beams, in particular laser beams. Additionally, the scanning device 100 comprises a micromechanical component 80, as shown, by way of example, in FIGS. 1 and 2. The micromechanical component 100 is in particular configured as a micromirror device and serves to deflect the light beams. Preferably, two micromechanical components are even provided in series in the beam path, in which the adjustable part is rotated in each case about a different axis of rotation, which axes of rotation are essentially perpendicular relative to each other. In particular, the scanning device 100 is configured as a lidar sensor. Alternatively, the scanning device 100 is configured as a microscanning device for smart glasses. Further possible applications are scanning the environment with a depth measurement of the laser emitters, e.g., in smartphones, for which the micromirror is suitable due to its miniaturization. With the spectral analysis of an optical beam, the environment can also be analyzed for certain substances. In this context, a further optical component 90 for redirecting, in particular for guiding, the light beams into the retina of the user of the smart glasses is optionally provided. The optical component 90 is in particular configured as a holographic optical element or as a waveguide.

What is claimed is:

1. A micromechanical component, comprising:
an adjustable part;
a first holder for the adjustable part;
a first connecting structure, wherein the first connecting structure is configured to connect the adjustable part to the first holder along a first axis of symmetry of the adjustable part that runs perpendicular to an axis of rotation of the adjustable part; and
a first electrical conductor for detecting a breakage within the first connecting structure, wherein the first electrical conductor runs along the first connecting structure at least partially at an angle to the first axis of symmetry of the adjustable part, at an angle between 0° and 90° relative to the first axis of symmetry.

2. The micromechanical component according to claim 1, wherein the first electrical conductor, in a first region of the first connecting structure aligned towards the first holder, runs parallel to the first axis of symmetry, and, in a second region of the first connecting structure aligned towards the adjustable part, runs partially at an angle to the first axis of symmetry, the angle being between 0° and 90° relative to the first axis of symmetry.

3. The micromechanical component according to claim 2, wherein the first electrical conductor, in a plan view, has a combined Y-shaped course in the first region and second region of the first connecting structure.

4. The micromechanical component according to claim 1, wherein the first electrical conductor, in a third region of the first connecting structure which is aligned towards the first holder, runs at an angle to the first axis of symmetry, at an angle between 0° and 90° relative to the first axis of symmetry, and, in a fourth, central region of the first connecting structure, runs parallel to the first axis of symmetry, and, in a fifth region of the first connecting structure which is aligned towards the adjustable part, runs at least partially at an angle to the first axis of symmetry, at an angle between 0° and 90° relative to the first axis of symmetry.

5. The micromechanical component according to claim 1, wherein the first electrical conductor runs along the first connecting structure completely at an angle to the first axis of symmetry.

6. The micromechanical component according to claim 1, wherein the first electrical conductor is configured to be symmetrical to the first axis of symmetry along the first connecting structure, in a plan view.

7. The micromechanical component according to claim 1, wherein the first holder has a frame shape.

8. The micromechanical component according to claim 1, further comprising:
a second connecting structure, wherein the second connecting structure is configured to connect the adjustable part along the first axis of symmetry of the adjustable part with the first holder, wherein the first electrical conductor or a second electrical conductor of the micromechanical component is configured to detect a breakage within the second connecting structure and runs partially at an angle between 0° and 90° relative to the first axis of symmetry of the adjustable part, along the second connecting structure, wherein the first connecting structure and the second connecting structure are arranged on opposite sides of the adjustable part.

9. The micromechanical component according to claim 8, wherein the first electrical conductor runs from the first connecting structure to the second connecting structure along the first holder.

10. The micromechanical component according to claim 9, wherein the first electrical conductor completely frames the adjustable part.

11. The micromechanical component according to claim 1, wherein the first electrical conductor runs partially on and/or inside the adjustable part.

12. The micromechanical component according to claim 1, wherein the first connecting structure and/or the second connecting structure are configured as webs.

13. The micromechanical component according to claim 1, wherein the adjustable part is configured as a micromirror.

14. The micromechanical component according to claim 1, further comprising:
a second fixed holder, a first spring, and second spring, wherein the first spring and the second spring are configured to suspend the first holder from the second fixed holder, adjustably about the first axis of rotation of the adjustable part.

15. A microscanning device, comprising:
a micromechanical component, including:
an adjustable part,
a first holder for the adjustable part,
a first connecting structure, wherein the first connecting structure is configured to connect the adjustable part to the first holder along a first axis of symmetry of the adjustable part that runs perpendicular to an axis of rotation of the adjustable part, and
a first electrical conductor for detecting a breakage within the first connecting structure, wherein the first electrical conductor runs along the first connecting structure at least partially at an angle to the first axis of symmetry of the adjustable part, at an angle between 0° and 90° relative to the first axis of symmetry.
